(19) United States
(12) Patent Application Publication
(10) Pub. No.: US 2008/0106307 A1
(43) Pub. Date: May 8, 2008

(54) Voice coil driving device and method for applying electric current

(75) Inventors: Yong-Gu LEE, Bucheon-si (KR); Young-Kwon YOON, Seoul (KR); Myoung-Won KIM, Seongnam-si (KR)

Correspondence Address: CHA & REITER, LLC, 210 ROUTE 4 EAST STE 103, PARAMUS, NJ, 07652, US

(73) Assignee: Samsung Electronics Co., LTD.

(21) Appl. No.: 11/982,684

(22) Filed: Nov. 2, 2007

(30) Foreign Application Priority Data
Nov. 2, 2006 (KR) 2006-107717

(51) Int. Cl. H03B 1/00

(52) U.S. Cl. 327/110

(57) ABSTRACT

A voice coil type driving device includes: a voice coil for securing a driving force depending on applied electric current; a position level generator for generating control signals so as to control the electric current applied to the voice coil in multiple levels; and a driving circuit for controlling the electric current applied to the voice coil according to the control signals generated in the position level generator, and a method for applying electric current in a voice coil type driving device, wherein electric current is applied in multiple steps.

### CLAIM OF PRIORITY

This application claims priority to an application entitled “Voice Coil Driving Device And Method For Applying Electric Current,” filed in the Korean Intellectual Property Office on Nov. 2, 2006 and assigned Serial No. 2006-107717, the contents of which are hereby incorporated by reference.

### BACKGROUND OF THE INVENTION

1. Field of the Invention

The present invention relates to an electric driving device, and more particularly, to a driving device and a driving method using a voice coil.

2. Description of the Related Art

Driving devices have been recently applied to various apparatuses, such as toys and robots that operate automatically, digital cameras, the lens of which a focal point can be automatically controlled, and hard-disks, etc. The driving device may use a piezoelectric element or a voice coil.

The driving device using a voice coil includes a spring, a permanent magnet, and a coil, etc, and can secure a driving force by the change of a magnetic field between a permanent magnet and the coil according to the change of electric current, which is applied to the coil.

FIG. 1 is a graph showing the characteristic of electric current applied to a conventional voice coil. As shown, the electric current is applied to the voice coil in a single step in order to obtain a necessary driving force.

The voice coil to which the electric current is applied as shown in FIG. 1 has a dynamic transition characteristic shown in the graph of FIG. 2A. Meanwhile, FIG. 2B is a graph showing the dynamic transition characteristic of the voice coil when a capacitor is attached to the voice coil in order to restrain the dynamic transition characteristic of the voice coil.

The dynamic transition characteristic of the voice coil, as shown in FIGS. 2A and 2B, is changed according to the intensity of electric current applied to the voice coil, and can be described in three divisions of over-damping, under-damping, and critical-damping until the voice coil is normalized after having the dynamic transition characteristic.

The above-mentioned damping corresponds to a movement characteristic such as change of in an elastic movement, and refers to a unstable change of movement during the time taken for the voice coil to reach an initially intended movement characteristic in a state where the voice coil has the dynamic transition characteristic. The critical-damping, as described above, refers to the movement characteristic in the same case of the movement characteristic of the voice coil, which is initially intended, the under-damping refers to downward movement characteristic on the basis of the critical-damping, and the over-damping refers to upward movement characteristic on the basis of the critical-damping.

However, there is a disadvantage in that, when the conventional voice coil is applied to equipment which needs a precise driving force, such as one for automatically controlling a focal length of a lens, etc., during a short time, time delay, etc are caused by the dynamic transition characteristic and the damping phenomenon.

FIG. 3 is a graph showing the dynamic transition characteristic of the voice coil in which a high-capacity capacitor is used in order to restrain the dynamic transition characteristic of the voice coil. As shown in FIG. 3, in the case that the capacitor is used in the voice coil, there is a problem in that reaction time delay is caused, and the application of the voice coil to potable apparatuses which need to be miniaturized is limited because of the volume of the capacitor.

### SUMMARY OF THE INVENTION

Accordingly, the present invention has been made to solve the above-mentioned problems occurring in the prior art and provides additional advantages, by providing a driving device and a driving method having a voice coil for restraining time delay and over-damping.

In accordance with an aspect of the present invention, a voice coil type driving device includes: a voice coil for securing a driving force depending on applied electric current; a position level generator for generating control signals so as to control the electric current applied to the voice coil in multiple levels; and a driving circuit for controlling the electric current applied to the voice coil according to the control signals generated in the position level generator.

In accordance with another aspect of the present invention, there is provided a method for applying electric current in a voice coil type driving device, wherein electric current is applied in multiple steps.

### BRIEF DESCRIPTION OF THE DRAWINGS

The above features and advantages of the present invention will be more apparent from the following detailed description taken in conjunction with the accompanying drawings, in which:

FIG. 1 is a graph illustrating the change of electric current according to the change of the time, in which the electric current is applied to the conventional voice coil type driving device;

FIGS. 2A and 2B are graphs showing the dynamic characteristic of the conventional voice coil type driving device;

FIG. 3 is a graph illustrating the dynamic characteristic of the conventional voice coil type driving device including a capacitor;

FIG. 4 is a schematic view showing the configuration of a voice coil type driving device according to the present invention;

FIG. 5 is a view showing the change of electric current according to the change of time, in which the electric current is applied to the voice coil type driving device shown in FIG. 4; and

FIG. 6 is a graph showing the dynamic characteristic of the voice coil type driving device according to the present invention.

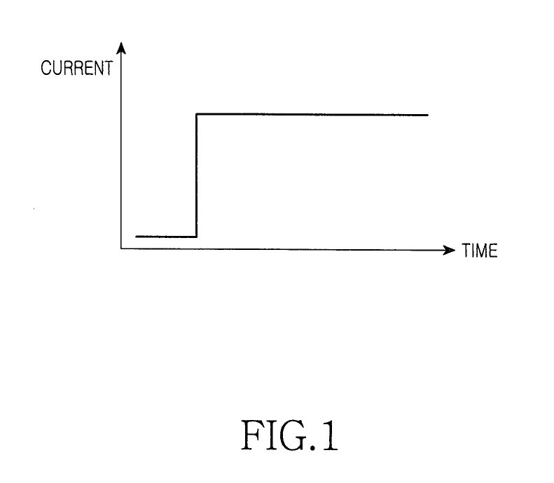

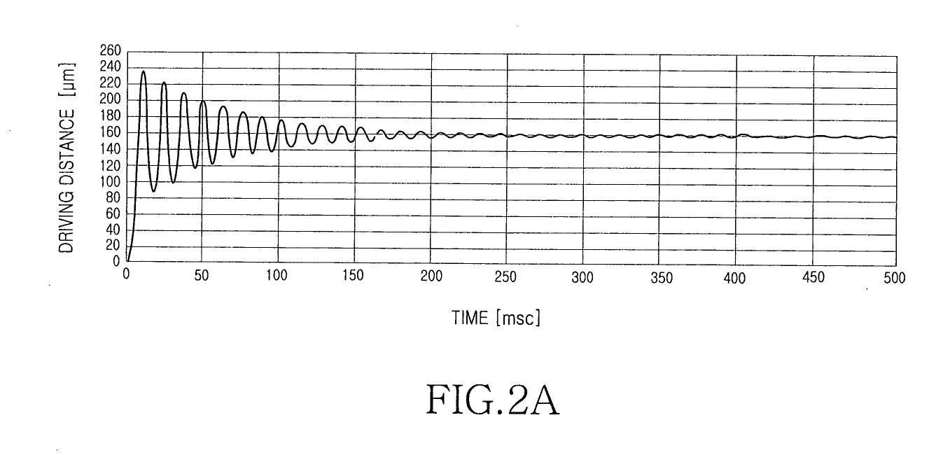

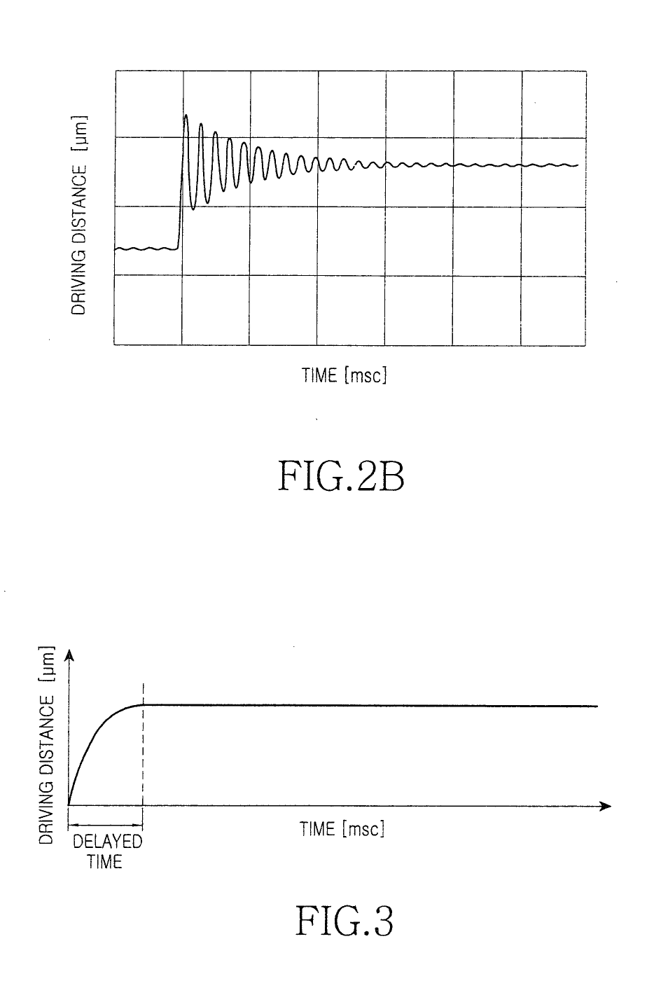

### DETAILED DESCRIPTION OF THE EXEMPLARY EMBODIMENT

Hereinafter, an exemplary embodiment of the present invention will be described with reference to the accompanying drawings. For the purposes of clarity and simplicity, a detailed description of known functions and configurations incorporated herein will be omitted as it may make the subject matter of the present invention unclear.

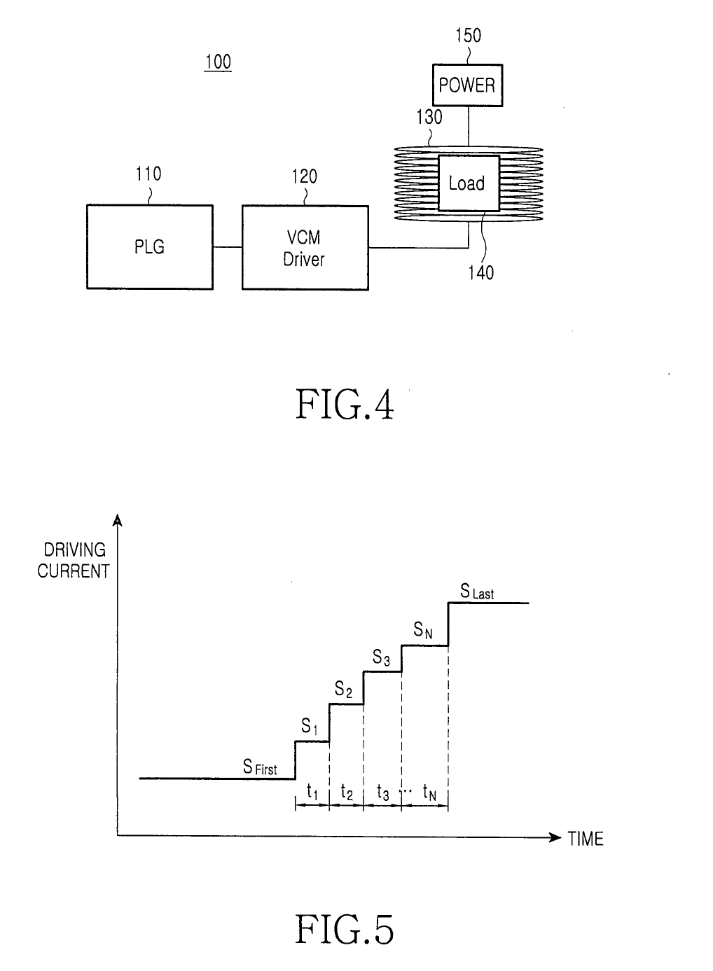

FIG. 4 is a schematic view showing the configuration of a voice coil type driving device according to the present invention. Referring to FIG. 4, the voice coil type driving device 100 according to the present invention includes a permanent magnet 140, a voice coil 130 which has the permanent magnet 140 disposed at the center portion thereof and secures a driving force depending on applied electric current, a position level generator 110 for generating control signals used for controlling the electric current applied to the voice coil 130 in a plurality of steps, a voice coil motor (VCM) driver 120 for controlling the electric current applied to the voice coil 130 according to the control signals of the position level generator 110, and an electric power source 150. The VCM driver 120 may include a high-current amplifier.

The voice coil 130 has magnetic poles, polarities of which are changed depending on the change of the applied electric current, so that a driving force is generated between the voice coil 130 and the permanent magnet 140. FIG. 5 is a view showing the change of the electric current applied to the voice coil type driving device 100, as shown in FIG. 4, according to the change of time. As shown in FIG. 5, the voice coil type driving device 100 according to the present invention is driven by the electric current applied thereto in divided multiple steps according to the controlling by the position level generator 110.

The voice coil type driving device 100 can obtain the necessary dynamic characteristic according to the number of steps in which the electric current is to be applied, maintenance time (t1, t2, t3˜t4) of each step, and strength (Sfirst˜Slast) of the electric current to be applied in the each step. The strength (S1˜SN) of the applied electric current in the each step can be defined by a percentage. A method for applying driving electric current in respective steps so as to improve the dynamic characteristic, can be applied to a driving device using a piezoelectric element and a driving device using a shape memory alloy as well as to the voice coil type driving device according to the present invention.

When the specific numbers of current steps in which the electric current will be applied to the voice coil type driving device 100 according to the present invention, for an example, 4 steps (N=4) are applied, 1 ms as the maintenance time in each step can be given, and S1 is 0.314, S2 is 0.401, S3 is 0.773, and S4 is 0.884.

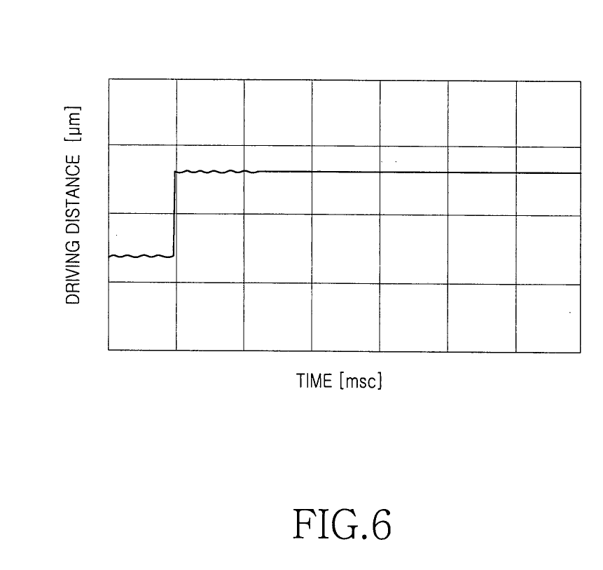

The electric current applied to the voice coil 130 increases gradually, and the electric current is regularly applied to the voice coil during the predetermined time period in each current step. Particularly, since the electric current is applied to the voice coil in different manners in the respective current steps, it is possible to minimize the occurrence of damping, as shown in the graph of FIG. 6, which shows the dynamic characteristic of the voice coil type driving device 100.

Even though the capacitor is not attached to the driving device provided with the voice coil according to the present invention, the driving device can secure the stable dynamic characteristic, and can restrain over-damping and time delay. Particularly, the present invention is easily employed to portable apparatuses which need a driving device having small volume.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A voice coil type driving device, comprising:
a voice coil for securing a driving force depending on applied electric current;
a position level generator for generating control signals so as to control the electric current applied to the voice coil in multiple levels; and
a driving circuit for controlling the electric current applied to the voice coil according to the control signals generated in the position level generator.

2. The voice coil type driving device as claimed in claim 1, further comprising a permanent magnet which passes through the center of the voice coil.

3. The voice coil type driving device as claimed in claim 1, wherein the driving circuit comprises a high-current amplifier.

4. The voice coil type driving device as claimed in claim 1, wherein the voice coil, the position level generator, and the driving circuit are employed in a portable apparatus.

5. A method for applying electric current in a voice coil type driving device, wherein electric current is applied in multiple steps.

6. The method as claimed in claim 5, wherein the applied electric current increases gradually and is regularly applied in respective current steps during a predetermined time period.

7. The method as claimed in claim 5, wherein the electric current is applied in the multiple steps under a control of a position level generator

8. The method as claimed in claim 5, wherein the voice coil type driving device comprises a portable apparatus.
